(19) United States
(12) Patent Application Publication
(10) Pub. No.: US 2025/0048599 A1
(43) Pub. Date: Feb. 6, 2025

(54) INTEGRATED CABINET AND DATA CENTER COMPUTER ROOM

(71) Applicant: Hebei Qinhuai Data Co., Limited., Zhangjiakou City (CN)

(72) Inventors: Binghua ZHANG, Zhangjiakou City (CN); Hao WANG, Zhangjiakou City (CN)

(21) Appl. No.: 18/789,257

(22) Filed: Jul. 30, 2024

(30) Foreign Application Priority Data
Aug. 1, 2023 (CN) 202310963261.2

(51) Int. Cl. H05K 7/20

(52) U.S. Cl. CPC H05K 7/20772; H05K 7/20281

(57) ABSTRACT

Embodiments of the present disclosure provide an integrated cabinet and data center computer room. A heat exchange apparatus is arranged inside a distributed CDU, where an external passage and an internal passage are arranged inside the heat exchange apparatus. A water-cooled backplane is communicated with the external passage, the external passage is connected to a liquid return main pipeline, the liquid return main pipeline is connected to a first cooling tower, the water-cooled backplane is connected to a liquid supply main pipeline, and the liquid supply main pipeline is connected to the first cooling tower. The internal passage is connected to a second cooling tower, the second cooling tower is connected to a liquid inlet of a region to be cooled, and a liquid outlet of the region to be cooled is connected to a liquid inlet of the internal passage.

### CROSS REFERENCE TO RELATED APPLICATION

This application claims priority to Chinese Patent Application No. 202310963261.2, titled “INTEGRATED CABINET AND DATA CENTER COMPUTER ROOM” and filed to the China National Intellectual Property Administration on Aug. 1, 2023, the entire contents of which are incorporated herein by reference.

### TECHNICAL FIELD

Embodiments of the present disclosure relate to the field of data center cooling technology, and more particularly, to an integrated cabinet and a data center computer room.

### BACKGROUND

In the information era, with the rapid development of technologies such as artificial intelligence, cloud computing, and the Internet of Things, many large data centers have emerged.

The more IT devices are arranged in cabinets of the data centers, the higher the overall power consumption is. Meanwhile, the more heat is generated. To better dissipate heat from the IT devices, liquid cooling technologies have been widely applied. Common liquid cooling solutions include cold plate cooling, immersion cooling, and spray cooling. The cold plate cooling is the most widely used. The cold plate cooling includes two technical directions: distributed cooling dispensing unit (CDU) and centralized CDU. In most cases, the cold plate cooling is the centralized CDU, which distributes cooling mediums to each of the cabinets. After the cabinets obtain the cooling mediums, the cooling mediums are distributed to each of the IT devices in the cabinets.

The above centralized CDU cooling solution is easy to cause excessive liquid supply flow, leads to higher energy consumption, and easily shorten service life of the CDU.

### SUMMARY

Embodiments of the present disclosure provide an integrated cabinet and a data center computer room. The integrated cabinet adopts a cabinet level CDU, and the integrated cabinet is decoupled from a liquid-cooled server to avoid excessive liquid supply flow, thereby ensuring lower energy consumption and extending service life of the cabinet level CDU.

In a first aspect, the embodiments of the present disclosure provide an integrated cabinet, which includes:

a cabinet body 1, a power supply module 2, a water-cooled backplane 3, and a distributed cooling dispensing unit (CDU) 4. The distributed CDU 4 is integrated at a bottom of the cabinet body 1, the water-cooled backplane 3 is openable and closable and is arranged on a side surface of the cabinet body 1, the power supply module 2 is arranged inside the cabinet body 1, and the cabinet body 1 has a shelving region 5 for accommodating an IT device.

A heat exchange apparatus 41 is arranged on the distributed CDU 4, and an external passage 411 and an internal passage 412 are arranged inside the heat exchange apparatus 41.

A liquid outlet of the water-cooled backplane 3 is communicated with a liquid inlet of the external passage 411, a liquid outlet of the external passage 411 is connected to a liquid return main pipeline, the liquid return main pipeline is connected to an inlet of a first cooling tower, a liquid inlet of the water-cooled backplane 3 is connected to a liquid supply main pipeline, and the liquid supply main pipeline is connected to an outlet of the first cooling tower.

A liquid outlet of the internal passage 412 is connected to an inlet of the second cooling tower, an outlet of the second cooling tower is connected to a liquid inlet of a region to be cooled, and a liquid outlet of the region to be cooled is connected to a liquid inlet of the internal passage 412.

In a second aspect, the embodiments of the present disclosure provide a data center computer room, which includes a computer room internally provided with the integrated cabinet as described in the first aspect or various possible implementations of the first aspect.

In the integrated cabinet and the data center computer room provided in the embodiments of the present disclosure, the integrated cabinet includes a cabinet body, a power supply module, a water-cooled backplane, and a distributed CDU. The distributed CDU is integrated at the bottom of the cabinet body, the water-cooled backplane is openable and closable and is arranged on the side surface of the cabinet body, the power supply module is arranged inside the cabinet body, and the cabinet body has a shelving region for accommodating an IT device. A heat exchange apparatus is arranged inside the distributed CDU, where an external passage and an internal passage are arranged inside the heat exchange apparatus. A liquid outlet of the water-cooled backplane is communicated with a liquid inlet of the external passage, a liquid outlet of the external passage is connected to a liquid return main pipeline, the liquid return main pipeline is connected to an inlet of a first cooling tower, a liquid inlet of the water-cooled backplane is connected to a liquid supply main pipeline, and the liquid supply main pipeline is connected to an outlet of the first cooling tower. A liquid outlet of the internal passage is connected to an inlet of a second cooling tower, an outlet of the second cooling tower is connected to a liquid inlet of a region to be cooled, and a liquid outlet of the region to be cooled is connected to a liquid inlet of the internal passage. By adopting this solution, the integrated cabinet adopts a cabinet level CDU, and the integrated cabinet is decoupled from a liquid-cooled server to avoid excessive liquid supply flow, thereby ensuring lower energy consumption and extending service life of the cabinet level CDU. Moreover, the decoupling of the cabinet from an IT device facilitates the integrated cabinet to fit with various IT devices. In addition, an air-cooled backplane in a primary loop is connected in series with the distributed CDU, such that liquid cooling and air cooling are completely provided by the integrated cabinet, which greatly simplifies the structure of the integrated cabinet.

### BRIEF DESCRIPTION OF THE DRAWINGS

To describe the technical solutions of the embodiments of the present disclosure more clearly, the accompanying drawings required in the description of the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1A is a front perspective view of an integrated cabinet according to an embodiment of the present disclosure;

FIG. 1B is a rear view of a water-cooled backplane of the integrated cabinet shown in FIG. 1A in an open state;

FIG. 1C is a rear view of the water-cooled backplane of the integrated cabinet shown in FIG. 1A in a closed state;

FIG. 1D is a side view of the integrated cabinet shown in FIG. 1A;

FIG. 2A is a schematic diagram of refrigeration principles of the integrated cabinet according to an embodiment of the present disclosure;

FIG. 2B is another schematic diagram of the refrigeration principles of the integrated cabinet according to an embodiment of the present disclosure; and

FIG. 3 is a schematic exploded view of the water-cooled backplane of the integrated cabinet according to an embodiment of the present disclosure.

### DETAILED DESCRIPTION

To make the objectives, technical solutions and advantages of the present disclosure clearer, the embodiments of the present disclosure will be further described in detail below with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal communication between two apparatuses, elements, or components. The specific significations of the above terms in the present disclosure may be understood in the light of specific conditions by persons of ordinary skill in the art.

In the era of Internet, people's lives are filled with a large amount of information data. Storage and processing of the massive amount of information data generally rely on numerous data centers. With the development of scale and integration of these data centers, density and power of IT devices in the data centers are also increasing day by day. To dissipate heat from the IT devices, liquid cooling technologies are becoming more and more popular.

The liquid cooling technologies are mainly classified into cold plate cooling, immersion cooling, and spray cooling. The cold plate cooling is the most widely used. In the cold plate cooling, according to a cooling threshold of a cooling dispensing unit (CDU), the cold plate cooling is further classified into a distributed CDU and a centralized CDU. In most cases, the cold plate cooling is the centralized CDU, which distributes cooling mediums to each of the cabinets. After the cabinets obtain the cooling mediums, the cooling mediums are distributed to each of the IT devices in the cabinets.

In most cases, the IT devices are put on shelves in batches, so the centralized CDU may easily lead to excessive liquid supply flow, causing higher energy consumption and shortening the service life of the CDU. Moreover, when one CDU is connected to a plurality of servers and a new server is added, it is required to reset the CDU, such as setting distribution of the liquid flow, which is complex in processes and prone to errors, thus adversely affecting stable operation of the data center.

On this basis, the embodiments of the present disclosure provide an integrated cabinet and a data center. The integrated cabinet adopts a cabinet level CDU, and the integrated cabinet is decoupled from the IT device such as a liquid-cooled server to avoid excessive liquid supply flow, thereby ensuring lower energy consumption and extending the service life of the cabinet level CDU.

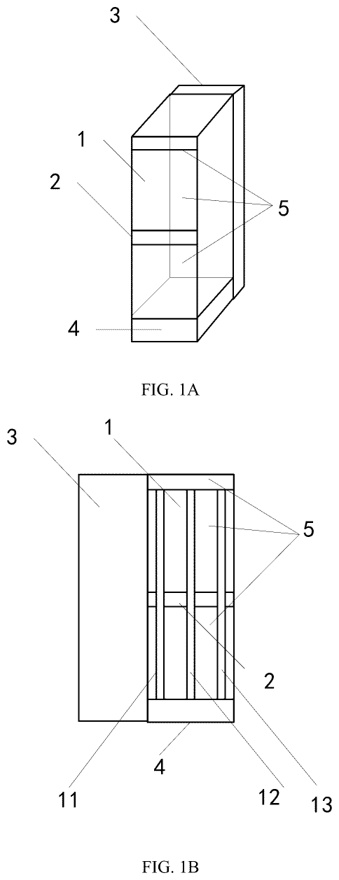

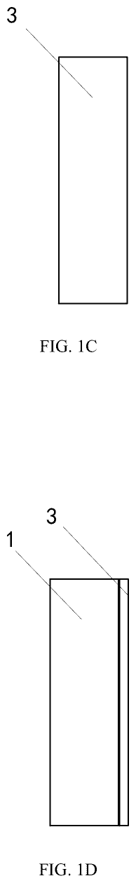

FIG. 1A is a front perspective view of the integrated cabinet according to the embodiments of the present disclosure, FIG. 1B is a rear view of a water-cooled backplane of the integrated cabinet shown in FIG. 1A in an open state, FIG. 1C is a rear view of the water-cooled backplane of the integrated cabinet shown in FIG. 1A in a closed state, and FIG. 1D is a side view of the integrated cabinet shown in FIG. 1A.

Referring to FIGS. 1A to 1D, the integrated cabinet provided in the embodiments of the present disclosure includes a cabinet body 1, a power supply module 2, a water-cooled backplane 3, and a distributed cooling dispensing unit (CDU) 4. The distributed CDU 4 is integrated at a bottom of the cabinet body 1, the water-cooled backplane 3 is openable and closable and is arranged on a side surface of the cabinet body 1, the power supply module 2 is arranged inside the cabinet body 1, and the cabinet body 1 has a shelving region 5 for accommodating the IT device.

In the embodiments of the present disclosure, the integrated cabinet adopts a cabinet level CDU. That is, the CDU is integrated with a liquid-cooled cabinet to form the integrated cabinet. The cabinet level CDU is a type of distributed CDU, which has features such as dispensing with deployment of secondary pipelines, adapting to different cabinet powers, easily matching with cabinet power consumption, and being available for on-demand use based on deployment of the IT device.

In FIGS. 1A to 1D, as a standard cabinet, the cabinet body 1 is used for deploying many types of devices such as servers and switches.

As a conventional device, the power supply module 2 is integrated with a power supply control system. To ensure that the IT device can be easily mounted and removed, the power supply module 2 prioritizes to concentrate power supply copper busbars, to provide centralized power supply to the IT device by means of a power shelf, a power module, and the power supply copper busbars. Blind mate operation is supported without the need for power cables, thus saving wiring space. The power supply copper busbars are arranged in a power distribution bus region of the integrated cabinet.

The water-cooled backplane 3 is internally provided with a heat exchanger, a fan, an electric control valve, a manual control valve, a temperature sensor, a pressure sensor, and a control system, etc. An overall control system of the integrated cabinet is arranged on a control interface of the water-cooled backplane 3. The overall control system, also known as a full liquid cold plate cooling system, is configured to control the water-cooled backplane, and the distributed CDU, etc. The heat exchanger, also known as a heat exchange coil or the like, is made of copper tubes, aluminum fins, or stainless steel tubes or aluminum micro channels.

The fan may be, for example, a 24V or 48V DC axial flow fan. The electric control valve, also known as a primary by-pass valve, is configured to regulate a liquid flow rate of the water-cooled backplane 3. In addition, the water-cooled backplane 3 is also provided with a power distribution module, a monitoring module, and a structural member, etc. The power distribution module is configured to provide power to a device such as the fan. The monitoring module is configured to control refrigeration devices including the distributed CDU4. The monitoring module has a display screen, and devices to be controlled in the integrated cabinet are all displayed on the display screen. For example, a first by-pass valve 42 and a second by-pass valve 43 in the distributed CDU4 are displayed on the display screen. Technicians can control the integrated cabinet by means of the monitoring module. The structural member may be, for example, a sheet metal structural member attached to the integrated cabinet.

The distributed CDU4 is internally provided with the first by-pass valve 42, the second by-pass valve 43, a heat exchange apparatus 41, a water pump, a pressure stabilizing device 44, a liquid replenishment device 45, a temperature sensor, a flow sensor, a pressure sensor, a filter, a one-way valve, and a manual valve, etc. The heat exchange apparatus 41 may be, for example, a plate heat exchanger, or a shell-and-tube heat exchanger, etc. When the heat exchange apparatus 41 is a plate heat exchanger, it may be a brazed plate heat exchanger. The primary loop and the secondary loop exchange heat at the heat exchange apparatus 41.

The integrated cabinet has a refrigeration bus region, which is internally provided with a liquid supply main pipeline and a liquid return main pipeline of a second cooling tower. The liquid supply main pipeline of the second cooling tower is provided with a first pipeline, and the liquid return main pipeline of the second cooling tower is provided with a second pipeline. The first pipeline is provided with a first branch pipe, the second pipeline is provided with a second branch pipe, and the first branch pipe and the second branch pipe are provided with a male quick connector or female quick connector for access of the IT device.

The shelving region 5 includes a network device shelving region positioned above the cabinet body 1, and server shelving regions positioned in a middle-upper part and a middle-lower part of the cabinet body 1. In the embodiments of the present disclosure, the network device is a conventional device with requirements for network direction. That is, the network device such as a switch is positioned above the cabinet body 1, and a network cable connected to the server is in a network bus region positioned in the middle at the rear of the cabinet body 1. The server is inserted from the front of the cabinet body 1, including components and parts such as guide rails and support brackets.

As a conventional device, the server may be a cold plate liquid-cooled server or an air-cooled server. In the embodiments of the present disclosure, a CPU and a GPU of the IT device are cooled by means of cold plate liquid cooling, while a hard disk and a graphics card of the IT device are cooled by means of an air cooling part.

The embodiments of the present disclosure do not limit a size of the integrated cabinet. For example, exclusive of the water-cooled backplane 3, the size of the cabinet body 1 is: height×width×depth=2,200 millimeters×600 mm×1,200 millimeters; inclusive of the water-cooled backplane 3, the size of the cabinet body 1 is 2,200 millimeters×900 millimeters×1,200 millimeters. The height of the distributed CDU4 is 4U, approximately 178 millimeters; and the height of the power supply module 2 is 3U, approximately 133 millimeters. The height of the network device shelving region is 3U, approximately 133 millimeters. The server shelving region includes two parts with a height of 36U, where one part is the middle-upper part of the cabinet body 1, with a height of 20U, approximately 889 mm, and the other part is the middle-lower part of the cabinet body 1, with a height of 16U, approximately 711 mm.

In FIGS. 1A to 1D, the backplane cabinet design integrates the cabinet body 1, the power supply module 2, the water-cooled backplane 3, and the distributed CDU together, resulting in a higher product integration. Compared to the centralized CDU, the cabinet level CDU improves delivery agility, and can meet needs of most customers.

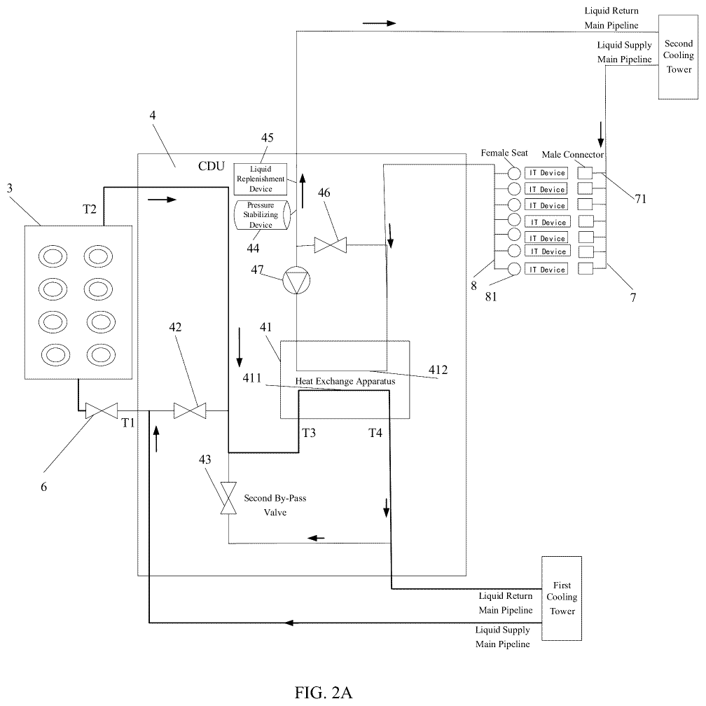

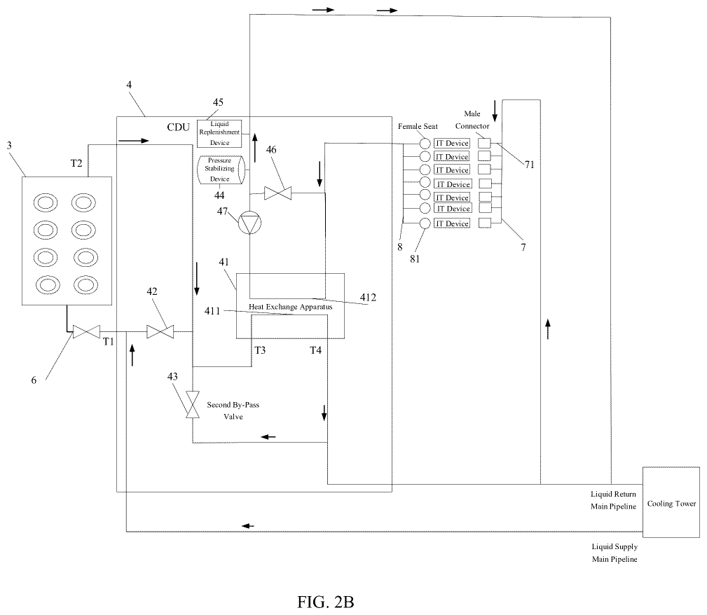

FIG. 2A is a schematic diagram of refrigeration principles of the integrated cabinet according to an embodiment of the present disclosure. Referring to FIG. 2A, a heat exchange apparatus 41 is arranged on the distributed CDU 4, and an external passage 411 and an internal passage 412 are arranged inside the heat exchange apparatus 41. A liquid outlet of the water-cooled backplane 3 is communicated with a liquid inlet of the external passage 411, a liquid outlet of the external passage 411 is connected to a liquid return main pipeline, the liquid return main pipeline is connected to an inlet of a first cooling tower, a liquid inlet of the water-cooled backplane 3 is connected to a liquid supply main pipeline, and the liquid supply main pipeline is connected to an outlet of the first cooling tower. A liquid outlet of the internal passage 412 is connected to an inlet of the second cooling tower, an outlet of the second cooling tower is connected to a liquid inlet of a region to be cooled, and a liquid outlet of the region to be cooled is connected to a liquid inlet of the internal passage 412.

In FIG. 2A, the IT device may be, for example, the network device or the server in the above shelving region. The CPU and the GPU of the IT device are cooled by means of cold plate liquid cooling, while the hard disk, the graphics card, the switch, the power distribution module, and the water pump are cooled by means of the air cooling part. The air cooling is provided by the water-cooled backplane 3, and the liquid cooling is provided by the distributed CDU4.

Referring to FIG. 2A, a bold black solid line represents the primary loop, and a dashed line represents the secondary loop. The heat exchange apparatus 41 is internally provided with the external passage 411 and the internal passage 412, where the external passage 411 forms a portion of the primary loop, and the internal passage 412 forms a portion of the secondary loop. Liquid in the primary loop and liquid in the secondary loop exchange heat in the heat exchange apparatus 41. A cooling liquid in the external passage 411 and a cooling liquid in the internal passage 412 do not blend with each other, and thus no adverse impact is caused to quality of the cooling liquid in the internal passage 412. The same cooling liquid or different cooling liquids may be used in the external passage 411 and the internal passage 412. The cooling liquid is also known as a cooling medium, or a working medium, etc.

The primary loop and the secondary loop are described in detail below, respectively.

The primary loop is first described.

Referring to FIG. 2A, the cooling provided by the first cooling tower flows out from the outlet into the liquid supply main pipeline, and then reaches the liquid inlet of the water-cooled backplane 3 through the liquid supply main pipeline to form the air cooling. A plurality of fans such as 24V or 48V DC axial flow fans are arranged in the water-cooled backplane 3. By running a proportional-integral-derivative (PID) control algorithm, return air temperature of the water-cooled backplane 3 can be adjusted. The integrated cabinet mentioned above also includes a primary by-pass valve 6, which is arranged at the liquid inlet of the water-cooled backplane 3. By running the PID algorithm, an opening degree of the primary by-pass valve 6 can be adjusted to achieve the objective of adjusting supply air temperature of the water-cooled backplane 3.

The air cooling flows out of the liquid outlet of the water-cooled backplane 3 and reaches the liquid inlet of the external passage 411 of the heat exchange apparatus 41. After the cooling liquid in the external passage 411 exchanges heat, in the heat exchange apparatus 41, with the cooling liquid in the internal passage 412, the cooling liquid in the external passage 411 flows out of the liquid outlet of the external passage 411, enters the liquid return main pipeline, and finally enters the first cooling tower, thereby forming a closed loop. The air cooling is used for cooling the hard drive, the graphics card, the switch, the power distribution module, the water pump, and so on of the IT device.

In the above closed loop, the cooling first passes through the water-cooled backplane 3, and then passes through the heat exchange apparatus 41, such that the air cooling part is connected in series with the liquid cooling part. In this way, the primary loop can provide both the air cooling and the liquid cooling, which simplifies the system to a certain extent and reduces engineering and regulation processes.

In addition, a portion of the cooling liquid flowing out through the liquid supply main pipeline of the first cooling tower flows towards the water-cooled backplane 3, and another portion of the cooling liquid flows directly into the liquid inlet of the external passage 411 through the first by-pass valve 42 to generate the liquid cooling. The liquid cooling is used for cooling the CPU, the GPU, and so on of the IT device. A path between the liquid supply main pipeline of the first cooling tower and the liquid inlet of the external passage 411 via the first by-pass valve 42 is not shown in the figure.

In the primary loop, temperature T1<temperature T2-temperature T3<temperature T4. The temperature T1 is the temperature at the liquid inlet of the water-cooled backplane 3, the temperature T2 is the temperature at the liquid outlet of the water-cooled backplane 3, the temperature T3 is the temperature at the liquid inlet of the external passage 411 of heat exchange apparatus 41, and the temperature T4 is the temperature at the liquid outlet of the external passage 411 of the heat exchange apparatus 41.

Next, the secondary loop is described.

Referring to FIG. 2A, after the cooling liquid from the second cooling tower flows out of the liquid outlet, it enters the liquid supply main pipeline of the second cooling tower. Next, the cooling liquid passes through the region to be cooled and takes away heat generated by a device to be cooled, and then reaches the internal passage 412 of the heat exchange apparatus 41. Next, the cooling liquid in the external passage 411 and the cooling liquid in the internal passage 412 exchange heat in the heat exchange apparatus 41. After the heat exchange is completed, the cooling liquid flows out of the liquid outlet of the internal passage 412, and then returns to the second cooling tower through the liquid return main pipeline of the second cooling tower, thereby forming a closed loop.

In the secondary loop, a region where the IT device is positioned is the region to be cooled, which is equivalent to the shelving region 5 in FIG. 1A. A bus region is arranged on an end face of the shelving region 5 with respect to the water-cooled backplane 3, and the bus region is used for installing the liquid supply main pipeline, the liquid return main pipeline, the network cable, and a power distribution cable, etc.

Referring to FIGS. 1A to 2A, after the IT device such as the network device and the server is put on the shelves, based on the primary loop, the cooling liquid in the first cooling tower reaches the water-cooled backplane 3 through the liquid supply main pipeline, and then enters the heat exchange apparatus 4 through the liquid inlet of the external passage 411 of the heat exchange apparatus 4. After exchanging heat with the cooling liquid in the secondary loop inside the heat exchange apparatus 4, the cooling liquid flows out of the liquid outlet of the external passage 411, and finally flows back into the first cooling tower through the liquid return main pipeline. In this primary loop, the cooling from the first cooling tower passes through the air-cooled backplane 3 and the heat exchange apparatus 4, which is equivalent to connecting the air-cooled backplane 3 and the heat exchange apparatus 4 in series.

Based on the secondary loop, the cooling liquid in the second cooling tower passes through the region to be cooled, absorbs the heat from the region to be cooled, and then enters the heat exchange apparatus 4 through the liquid inlet of external passage 412. The primary loop and the secondary loop exchange heat inside the heat exchange apparatus 4. After the heat exchange is completed, the cooling liquid flows out of the liquid outlet of the external passage 412, and reaches the second cooling tower through the liquid return main pipeline.

In the embodiments of the present disclosure, the first cooling tower of the primary loop and the second cooling tower of the secondary loop may be separately designed or may be the same cooling tower. The first cooling tower and the second cooling tower as shown in FIG. 2A are separately designed. Below, a detailed description is made to a case where the primary loop and the secondary loop share the same cooling tower. When the primary loop and the secondary loop share the same cooling tower, the first cooling tower and the second cooling tower mentioned above are the same cooling tower.

FIG. 2B is another schematic diagram of the refrigeration principles of the integrated cabinet according to an embodiment of the present disclosure. Referring to FIG. 2B, unlike FIG. 2A, the first cooling tower and the second cooling tower in FIG. 2A are two separate cooling towers. However, in FIG. 2B, there is only one cooling tower. That is, the first cooling tower and the second cooling tower are the same cooling tower. By adopting this solution, when there is only one cooling tower, the primary loop and the secondary loop share the same cooling tower. In this way, the cooling tower is fully utilized, an area occupied by the cooling tower is reduced, thereby achieving the objective of reducing the area occupied by the data center.

The integrated cabinet provided in the embodiments of the present disclosure includes a cabinet body, a power supply module, a water-cooled backplane, and a distributed CDU. The distributed CDU is integrated at the bottom of the cabinet body, the water-cooled backplane is openable and closable and is arranged on the side surface of the cabinet body, the power supply module is arranged inside the cabinet body, and the cabinet body has a shelving region for accommodating an IT device. A heat exchange apparatus is arranged inside the distributed CDU, where an external passage and an internal passage are arranged inside the heat exchange apparatus. A liquid outlet of the water-cooled backplane is communicated with a liquid inlet of the external passage, a liquid outlet of the external passage is connected to a liquid return main pipeline, the liquid return main pipeline is connected to an inlet of a first cooling tower, a liquid inlet of the water-cooled backplane is connected to a liquid supply main pipeline, and the liquid supply main pipeline is connected to an outlet of the first cooling tower. A liquid outlet of the internal passage is connected to an inlet of a second cooling tower, an outlet of the second cooling tower is connected to a liquid inlet of a region to be cooled, and a liquid outlet of the region to be cooled is connected to a liquid inlet of the internal passage. By adopting this solution, the integrated cabinet adopts a cabinet level CDU, and the integrated cabinet is decoupled from the IT device such as a liquid-cooled server to avoid excessive liquid supply flow, thereby ensuring lower energy consumption and extending service life of the cabinet level CDU. Moreover, the decoupling of the cabinet from the IT device facilitates the integrated cabinet to fit with various IT devices. In addition, the air-cooled backplane in the primary loop is connected in series with the distributed CDU, such that liquid cooling and air cooling are completely provided by the integrated cabinet, which greatly simplifies the structure of the integrated cabinet.

Alternatively, referring to FIG. 2A and FIG. 2B, a first by-pass valve 42 and a second by-pass valve 43 are further arranged on the distributed CDU 4 of the integrated cabinet, where the first by-pass valve 42 is arranged between the liquid inlet of the water-cooled backplane 3 and the liquid inlet of the external passage 411 to control cooling of the water-cooled backplane 3 and of the heat exchanger 4. The second by-pass valve 43 is arranged between the liquid outlet of the external passage 411 and the liquid inlet of the external passage 411 to control a temperature of the heat exchanger 4.

For example, the first by-pass valve 42, also known as a water-cooled backplane by-pass valve, is connected to a controller (not shown in the figure). By running the PID control algorithm, the controller adjusts the opening degree of the first by-pass valve 42, thereby adjusting water supply temperature of the heat exchange apparatus 4.

Generally, the first by-pass valve 42 is in a closed state. When the temperature of the secondary loop is higher, that is, when the temperature at the liquid outlet of the internal passage 412 is higher, the first by-pass valve 42 is opened, such that a portion of the cooling liquid from the first cooling tower enters the water-cooled backplane 3, and another portion of the cooling liquid reaches the liquid inlet of the external passage 411 through the first by-pass valve 42, and then enters the external passage, to increase intensity of the heat exchange. In this way, the temperature at the liquid outlet of the internal passage 412 is reduced. By adjusting the opening degree of the first by-pass valve 42, the controller can regulate a flow rate of the cooling liquid entering the external passage 411 through the first by-pass valve 42.

In the above embodiments, when the opening degree of the first by-pass valve 42 increases, more cooling liquid directly enters the heat exchange apparatus through the first by-pass valve 42, which is equivalent to increasing the liquid cooling. When the opening degree of the first by-pass valve 42 decreases, more cooling liquid enters the water-cooled backplane, which is equivalent to increasing the air cooling.

The second by-pass valve 43, also known as a heat exchanger by-pass valve, is connected to the controller (not shown in the figure). By running the PID control algorithm, the controller adjusts the opening degree of the second by-pass valve 43, thereby adjusting the temperature of the heat exchange apparatus 4.

Generally, the second by-pass valve 43 is in a closed state. When the temperature of the secondary loop is lower, that is, when the temperature at the liquid outlet of the internal passage 412 is lower, the second by-pass valve 43 is opened, such that a portion of the cooling liquid flowing out of the liquid outlet of the external passage 411 returns to the first cooling tower through the liquid return main pipeline, and another portion of the cooling liquid re-enters the external passage 411 through the second by-pass valve 43, as shown by dot dash lines in FIG. 2A and FIG. 2B. Because the cooling liquid flowing out of the liquid outlet of external passage 411 is a cooling liquid subjected to heat exchange, its temperature is higher. After the cooling liquid with higher temperature returns to the external passage 411, it can reduce the intensity of heat exchange, such that the temperature at the liquid outlet of the internal passage 412 rises.

By adopting this solution, by means of a design of connecting the water-cooled backplane in series with the distributed CDU and by means of the first by-pass valve and the second by-pass valve mentioned above, the controller of the integrated cabinet can flexibly adjust a ratio of the air cooling to the liquid cooling, such that the integrated cabinet freely fits to different IT devices, thereby increasing a range of application of the integrated cabinet.

Alternatively, referring to FIG. 2A and FIG. 2B again, the integrated cabinet also includes a primary by-pass valve 6, which is arranged at the liquid inlet of the water-cooled backplane 3 to control cooling entering the water-cooled backplane 3.

For example, the primary by-pass valve 6 is arranged near the liquid inlet of the water-cooled backplane 3. The controller of the integrated cabinet can adjust the opening degree of the primary by-pass valve 6 by running the PID algorithm, thereby achieving the objective of adjusting the supply air temperature of the water-cooled backplane 3. The adjustment manner is simple and the structure is simple. In practice, by adjusting the primary by-pass valve 6 and the first by-pass valve 42, the controller can adjust the cooling entering the water-cooled backplane 3, thereby adjusting the ratio of the air cooling to the water cooling.

Alternatively, in the above embodiments, a pressure stabilizing device 44 and a liquid replenishment device 45 are further arranged on the distributed CDU 4, and the pressure stabilizing device 44 and the liquid replenishment device 45 are sequentially arranged at the liquid outlet of the internal passage 412.

For example, referring to FIG. 2A and FIG. 2B, the pressure stabilizing device 44 and the liquid replenishment device 45 are sequentially arranged on a pipeline between the liquid outlet of the internal passage 411 of the heat exchange apparatus 4 and the inlet of the second cooling tower. The pressure stabilizing device 44 is configured to provide stable pressure to the secondary loop, mainly including a pressure stabilizing tank, etc. The liquid replenishment device 45 is configured to replenish the working medium for the secondary loop, mainly including a liquid replenishment tank, a liquid replenishment pump, or the like.

By adopting this solution, the pressure stabilizing device and the liquid replenishment device are arranged on the secondary loop to ensure stable pressure and sufficient working medium in the secondary loop, thereby achieving the objective of ensuring cooling effects.

Alternatively, in the above embodiments, a secondary by-pass valve 46 and a liquid cooling pump 47 are further arranged on the distributed CDU 4, where the secondary by-pass valve 46 is arranged between the liquid outlet and the liquid inlet of the internal passage 412, and the liquid cooling pump 47 is arranged between the liquid outlet of the internal passage 412 and the secondary by-pass valve 46.

Referring to FIG. 2A and FIG. 2B, the secondary by-pass valve 46 and the liquid cooling pump 47 are connected to the controller (not shown) of the integrated cabinet. The secondary by-pass valve is an electric by-pass valve, the liquid cooling pump 47 is a variable frequency water pump, and the liquid cooling pump 47 is configured to provide power to the working medium in the secondary loop. The controller adjusts a frequency of the liquid cooling pump according to a flow rate of the secondary loop or a hydraulic pressure difference between the liquid supply main pipeline and the liquid return main pipeline. When the frequency of the liquid cooling pump is lower, the secondary by-pass valve is opened to reduce the pressure difference for the secondary loop, such that the cooling liquid from the region to be cooled does not pass through the heat exchange apparatus 4, but directly enters the liquid return main pipeline through the secondary by-pass valve 46, and finally returns to the first cooling tower or the second cooling tower.

By adopting this solution, the secondary by-pass valve and the liquid cooling pump are arranged to ensure smooth flow of the cooling liquid in the secondary loop, thereby achieving the objective of improving the cooling effects.

Alternatively, in the above embodiments, a refrigeration bus region 11, a network bus region 12, and a power distribution bus region 13 are spaced on an end face of the cabinet body 1 opposite to the water-cooled backplane 3. The refrigeration bus region 11 is configured to arrange the liquid supply main pipeline and the liquid return main pipeline of the second cooling tower. The network bus region 12 is configured to arrange a network cable for the IT device to access network. The power distribution bus region 13 is configured to arrange a power supply line.

Referring to FIG. 1B, the refrigeration bus region 11 is configured to deploy the liquid supply main pipeline and the liquid return main pipeline. When the first cooling tower of the primary loop and the second cooling tower of the secondary loop are separate cooling towers, the liquid supply main pipeline and the liquid return main pipeline of the first cooling tower and the liquid supply main pipeline and the liquid return main pipeline of the second cooling tower are deployed in the refrigeration bus region 11. When the first cooling tower and the second cooling tower are the same cooling tower, the liquid supply main pipeline and the liquid return main pipeline of the cooling tower are deployed inside the refrigeration bus region.

The network bus region 12 is internally provided with network cable routers, including various types of network cables. When the IT device such as the network device or the server is put on the shelves, the network cables are connected.

Power distribution routers and centralized power supply copper busbars are deployed inside the power distribution bus region 13. Power is supplied to various IT devices inside the integrated cabinet by means of the power shelf, the power module, and the power supply copper busbars. Blind mate operation is supported without the need for power cables, thus saving wiring space. In addition, power also may be supplied by means of a power distribution unit (PDU) or the like, but the embodiments of the present disclosure are not limited thereto.

By adopting this solution, the refrigeration bus region, the network bus region, and the power distribution bus region are arranged on the end face of the cabinet body facing toward the water-cooled backplane, making the wiring neat and beautiful, facilitating wiring adjustment, and facilitating maintenance of the integrated cabinet.

Alternatively, in the above embodiments, the region to be cooled is provided with a first pipeline 7 and a second pipeline 8, where the first pipeline 7 is communicated with the liquid supply main pipeline of the second cooling tower, and the second pipeline 8 is connected to the liquid inlet of the internal passage 412. The first pipeline 7 is provided with a plurality of first branch pipes 71 for the IT device to access, the second pipeline 8 is provided with a plurality of second branch pipes 81 for the IT device to access, and the IT device is arranged between each of the plurality of first branch pipes 71 and each of the plurality of second branch pipes 81.

As an example, referring to FIG. 2A, FIG. 2B, and FIG. 1B, the region to be cooled is, for example, the shelving region of the IT device. The region to be cooled is provided with the first pipeline 7 and the second pipeline 8. The first pipeline 7 is provided with a plurality of first branch pipes 71, the second pipeline 8 is provided with a plurality of second branch pipes 81, and one IT device may be provided between each of the plurality of first branch pipes 71 and each of the plurality of second branch pipes 81. In this way, a plurality of IT devices may be provided. Every time when the IT devices are put on the shelves, by adopting this solution, the first pipeline and the second pipeline are arranged in the region to be cooled, the plurality of first branch pipes are arranged in the first pipeline, and the plurality of second branch pipes are arranged on the second pipeline. In this way, the plurality of IT devices can be put on the shelves, such that it is simple in structure and easy for management of the IT devices.

In the above embodiments, the first branch pipe 71 or the second branch pipe 81 is provided with a male quick connector, and the IT device has two female connectors. When the IT device is put on the shelves, the male connector on the first branch pipe 71 and the male connector on the second branch pipe 81 are inserted into the female connectors of the IT device, respectively. In some embodiments, the first branch pipe 71 or the second branch pipe 81 is provided with a female quick connector, and the IT device has two male connectors. When the IT device is put on the shelves, the two male connectors on the IT device are inserted into the female connector on the first branch pipe 71 or the second branch pipe 81, respectively.

Alternatively, each of the plurality of first branch pipes 71 and each of the plurality of second branch pipes 81 are provided with a blind mate quick connector.

As an example, in one embodiment, the male connector or the female connector is a quick connector. That is, the male connector or female connector on the first branch pipe 71 and the male connector or female connector on the second branch pipe 72 are blind mate quick connectors, and the IT device is connected to the cabinet body 1 by means of the blind mate quick connectors. When the blind mate quick connectors are used, there is no need to use power cables, thus achieving the objective of saving wiring space.

In another embodiment, the quick connector may also be a quick hose connector. After the IT device is connected through the quick hose connector on the first branch pipe 71 and the quick hose connector on the second branch pipe 72, flow of the cooling liquid can be achieved.

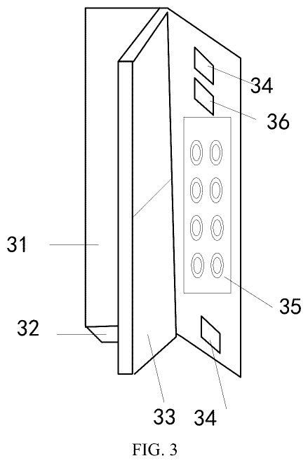

FIG. 3 is a schematic exploded view of the water-cooled backplane of the integrated cabinet according to an embodiment of the present disclosure. Referring to FIG. 3, the air-cooled backplane 3 includes a frame 31, a support base 32, a heat exchanger 33, an electrical module 34, a fan module 35, and a display screen 36. The frame 31 may be, for example, a sheet metal structural member attached to the cabinet body 1 of the integrated cabinet, the heat exchanger 33 may be, for example, a heat exchange coil, and the electrical module 34 is configured to supply power to the fan, and the display screen, etc. A plurality of fans are arranged inside the fan module 35, such as 24V or 48V DC axial flow fans. The display screen 36 is connected to the monitoring module to display various devices to be controlled inside the integrated cabinet, including various by-pass valves in the distributed CDU4.

Based on the integrated cabinet mentioned above, the embodiments of the present disclosure also provide a data center computer room, in which the integrated cabinet as described above is arranged.

Other embodiments of the present disclosure will be apparent to those skilled in the art from consideration of the specification and practice of the invention disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It is to be appreciated that the present disclosure is not limited to the exact construction that has been described above and illustrated in the accompanying drawings, and that various modifications and changes can be made without departing from the scope thereof. It is intended that the scope of the present disclosure only be limited by the appended claims.

What is claimed is:

1. An integrated cabinet comprising: a cabinet body (1), a power supply module (2), a water-cooled backplane (3), and a distributed cooling dispensing unit CDU (4), the distributed CDU (4) being integrated at a bottom of the cabinet body (1), the water-cooled backplane (3) being openable and closable and being arranged on a side surface of the cabinet body (1), the power supply module (2) being arranged inside the cabinet body (1), and the cabinet body (1) having a shelving region (5) for accommodating an IT device, wherein:
a heat exchange apparatus (41) is arranged on the distributed CDU (4), and an external passage (411) and an internal passage (412) are arranged inside the heat exchange apparatus (41);
a liquid outlet of the water-cooled backplane (3) is communicated with a liquid inlet of the external passage (411), a liquid outlet of the external passage (411) is connected to a liquid return main pipeline, the liquid return main pipeline is connected to an inlet of a first cooling tower, a liquid inlet of the water-cooled backplane (3) is connected to a liquid supply main pipeline, and the liquid supply main pipeline is connected to an outlet of the first cooling tower; and
a liquid outlet of the internal passage (412) is connected to an inlet of the second cooling tower, an outlet of the second cooling tower is connected to a liquid inlet of a region to be cooled, and a liquid outlet of the region to be cooled is connected to a liquid inlet of the internal passage (412).

2. The integrated cabinet according to claim 1, wherein a first by-pass valve (42) and a second by-pass valve (43) are further arranged on the distributed CDU (4), the first by-pass valve (42) is arranged between the liquid inlet of the water-cooled backplane (3) and the liquid inlet of the external passage (411) to control cooling of the water-cooled backplane (3) and of the heat exchanger (4); and
the second by-pass valve (43) is arranged between the liquid outlet of the external passage (411) and the liquid inlet of the external passage (411) to control a temperature of the heat exchanger (4).

3. The integrated cabinet according to claim 1 further comprising:
a primary by-pass valve (6) arranged at the liquid inlet of the water-cooled backplane (3) to control cooling entering the water-cooled backplane (3).

4. The integrated cabinet according to claim 3, wherein a pressure stabilizing device (44) and a liquid replenishment device (45) are further arranged on the distributed CDU (4), and the pressure stabilizing device (44) and the liquid replenishment device (45) are sequentially arranged at the liquid outlet of the internal passage (412) and a path before the second cooling tower.

5. The integrated cabinet according to claim 3, wherein a secondary by-pass valve (46) and a liquid cooling pump (47) are further arranged on the distributed CDU (4), the secondary by-pass valve (46) is arranged between the liquid outlet and the liquid inlet of the internal passage (412), and the liquid cooling pump (47) is arranged between the liquid outlet of the internal passage (412) and the secondary by-pass valve (46).

6. The integrated cabinet according to claim 3, wherein
the first cooling tower and the second cooling tower are the same cooling tower.

7. The integrated cabinet according to claim 3, wherein
a refrigeration bus region (11), a network bus region (12), and a power distribution bus region (13) are spaced on an end face of the cabinet body (1) opposite to the water-cooled backplane (3), wherein:
the refrigeration bus region (11) is configured to arrange the liquid supply main pipeline and the liquid return main pipeline of the first cooling tower, and the liquid supply main pipeline and the liquid return main pipeline of the second cooling tower;
the network bus region (12) is configured to arrange a network cable for the IT device to access network; and
the power distribution bus region (13) is configured to arrange a power supply line.

8. The integrated cabinet according to claim 3, wherein
the region to be cooled is provided with a first pipeline and a second pipeline, the first pipeline is communicated with the liquid supply main pipeline of the second cooling tower, and the second pipeline is connected to the liquid inlet of the internal passage (412); and
the first pipeline is provided with a plurality of first branch pipes for the IT device to access, the second pipeline is provided with a plurality of second branch pipes for the IT device to access, and the IT device is arranged between each of the plurality of first branch pipes and each of the plurality of second branch pipes.

9. The integrated cabinet according to claim 8, wherein
each of the plurality of first branch pipes and each of the plurality of second branch pipes are provided with a blind mate quick connector.

10. A data center computer room, comprising a computer room internally, the integrated cabinet comprising: a cabinet body (1), a power supply module (2), a water-cooled backplane (3), and a distributed cooling dispensing unit CDU (4), the distributed CDU (4) being integrated at a bottom of the cabinet body (1), the water-cooled backplane (3) being openable and closable and being arranged on a side surface of the cabinet body (1), the power supply module (2) being arranged inside the cabinet body (1), and the cabinet body (1) having a shelving region (5) for accommodating an IT device, wherein:
a heat exchange apparatus (41) is arranged on the distributed CDU (4), and an external passage (411) and an internal passage (412) are arranged inside the heat exchange apparatus (41);
a liquid outlet of the water-cooled backplane (3) is communicated with a liquid inlet of the external passage (411), a liquid outlet of the external passage (411) is connected to a liquid return main pipeline, the liquid return main pipeline is connected to an inlet of a first cooling tower, a liquid inlet of the water-cooled backplane (3) is connected to a liquid supply main pipeline, and the liquid supply main pipeline is connected to an outlet of the first cooling tower; and
a liquid outlet of the internal passage (412) is connected to an inlet of the second cooling tower, an outlet of the second cooling tower is connected to a liquid inlet of a region to be cooled, and a liquid outlet of the region to be cooled is connected to a liquid inlet of the internal passage (412).

11. The data center computer room according to claim 10, wherein a first by-pass valve (42) and a second by-pass valve (43) are further arranged on the distributed CDU (4), the first by-pass valve (42) is arranged between the liquid inlet of the water-cooled backplane (3) and the liquid inlet of the external passage (411) to control cooling of the water-cooled backplane (3) and of the heat exchanger (4); and
the second by-pass valve (43) is arranged between the liquid outlet of the external passage (411) and the liquid inlet of the external passage (411) to control a temperature of the heat exchanger (4).

12. The data center computer room according to claim 10 further comprising:
a primary by-pass valve (6) arranged at the liquid inlet of the water-cooled backplane (3) to control cooling entering the water-cooled backplane (3).

13. The data center computer room according to claim 12, wherein a pressure stabilizing device (44) and a liquid replenishment device (45) are further arranged on the distributed CDU (4), and the pressure stabilizing device (44) and the liquid replenishment device (45) are sequentially arranged at the liquid outlet of the internal passage (412) and a path before the second cooling tower.

14. The data center computer room according to claim 12, wherein a secondary by-pass valve (46) and a liquid cooling pump (47) are further arranged on the distributed CDU (4), the secondary by-pass valve (46) is arranged between the liquid outlet and the liquid inlet of the internal passage (412), and the liquid cooling pump (47) is arranged between the liquid outlet of the internal passage (412) and the secondary by-pass valve (46).

15. The data center computer room according to claim 12, wherein
the first cooling tower and the second cooling tower are the same cooling tower.

16. The data center computer room according to claim 12, wherein
a refrigeration bus region (11), a network bus region (12), and a power distribution bus region (13) are spaced on an end face of the cabinet body (1) opposite to the water-cooled backplane (3), wherein:
the refrigeration bus region (11) is configured to arrange the liquid supply main pipeline and the liquid return main pipeline of the first cooling tower, and the liquid supply main pipeline and the liquid return main pipeline of the second cooling tower;
the network bus region (12) is configured to arrange a network cable for the IT device to access network; and
the power distribution bus region (13) is configured to arrange a power supply line.

17. The data center computer room according to claim 12, wherein
the region to be cooled is provided with a first pipeline and a second pipeline, the first pipeline is communicated with the liquid supply main pipeline of the second cooling tower, and the second pipeline is connected to the liquid inlet of the internal passage (412); and
the first pipeline is provided with a plurality of first branch pipes for the IT device to access, the second pipeline is provided with a plurality of second branch pipes for the IT device to access, and the IT device is arranged between each of the plurality of first branch pipes and each of the plurality of second branch pipes.

18. The data center computer room according to claim 17, wherein
each of the plurality of first branch pipes and each of the plurality of second branch pipes are provided with a blind mate quick connector.
